(19) United States
(12) Patent Application Publication
(10) Pub. No.: US 2026/0255658 A1
(43) Pub. Date: Aug. 27, 2026

(54) METHOD FOR MANUFACTURING COMPLEMENTARY FIELD EFFECT TRANSISTOR

(71) Applicant: INSTITUTE OF MICROELECTRONICS, CHINESE ACADEMY OF SCIENCES, Beijing (CN)

(72) Inventors: Lei Cao, Beijing (CN); Huaxiang Yin, Beijing (CN); Qingzhu Zhang, Beijing (CN); Jiaxin Yao, Beijing (CN)

(21) Appl. No.: 19/322,528

(22) Filed: Sep. 8, 2025

(30) Foreign Application Priority Data
Feb. 21, 2025 (CN) 202510195870.7

(51) Int. Cl. H10D 84/01; H10D 30/00; H10D 30/01; H10D 30/43; H10D 62/10; H10D 62/832; H10D 84/85

(52) U.S. Cl. CPC H10D 84/0177; H10D 30/014; H10D 30/0191; H10D 62/121; H10D 62/832; H10D 84/0167; H10D 84/0181; H10D 30/43; H10D 30/502; H10D 84/851; H10D 84/856

(57) ABSTRACT

A method for manufacturing a complementary field-effect transistor is provided, including: providing a substrate; forming a nanosheet stacking structure at the substrate, where the nanosheet stacking structure includes a bottom structure located below an intermediate isolation layer and a top structure located above the intermediate isolation layer; removing first semiconductor layers in the bottom structure, and forming a bottom gate in a plurality of formed bottom gaps; and removing first semiconductor layers in the top structure, and forming a top gate in a plurality of formed top gaps.

### CROSS REFERENCE OF RELATED APPLICATION

This application claims the priority to Chinese Patent Application No. 202510195870.7, titled “METHOD FOR MANUFACTURING COMPLEMENTARY FIELD-EFFECT TRANSISTOR,” filed on Feb. 21, 2025 with the China National Intellectual Property Administration (CNIPA), which is incorporated herein by reference in its entirety.

### FIELD

The present disclosure relates to the field of semiconductors, and in particular to a method for manufacturing a complementary field-effect transistor.

### BACKGROUND

With the development of semiconductor technology, the feature size of integrated circuits continues to shrink. Traditional three-gate or double-gate fin field-effect transistors (FinFETs) are significantly limited by a short channel effect below 3-nanometer (nm) nodes, and nanosheet-gate all round fin field-effect transistors (Nanosheet-GAAFETs) that can alleviate the 3-nm node limitation have been developed. Furthermore, complementary field-effect transistors (CFET) have received extensive attention and research for being able to break a 1-nm node limitation.

Currently, in a procedure of manufacturing a complementary field-effect transistor, after nanosheets are released, P-type work function layers are first formed around all the nanosheets, and then a gate is deposited around part of the nanosheets. P-type work function layer(s) at surface(s) of nanosheet(s) not surrounded by the gate is (are) removed, and N-type work function layer(s) is (are) deposited at the surface of the nanosheet(s). In this way, the nanosheets are surrounded by different types of work function layers, and the complementary field-effect transistor is finally formed.

However, this manufacturing procedure has high requirements for a removal process of the P-type work function layers, and it is inclined to damage surfaces of the nanosheets when removing the P-type work function layers, which leads to a problem of channel interface.

### SUMMARY

In view of the above problem, the purpose of the present disclosure is to provide a method for manufacturing a complementary field-effect transistor, which can avoid damage to nanosheets, avoid a problem of channel interface, and improve the performance of a manufactured complementary field-effect transistor.

The present disclosure provides a method for manufacturing a complementary field-effect transistor, including:
providing a substrate;
forming a nanosheet stacking structure at the substrate, where the nanosheet stacking structure includes a bottom structure located below an intermediate isolation layer and a top structure located above the intermediate isolation layer, and the top structure and the bottom structure are each formed by alternately stacking first semiconductor layers and second semiconductor layers;
removing the first semiconductor layers in the bottom structure to form a plurality of bottom gaps, and forming a bottom gate in the plurality of bottom gaps; and
removing the first semiconductor layers in the top structure to form a plurality of top gaps, and forming a top gate in the plurality of formed top gaps,
wherein the step of removing the first semiconductor layers in the bottom structure is performed separately from the step of removing the first semiconductor layers in the top structure.

In an embodiment, the method further includes:
forming a release protection layer at a sidewall of the top structure,
where removing the first semiconductor layers in the bottom structure to form the plurality of bottom gaps, and forming the bottom gate in the plurality of bottom gaps includes:
removing the first semiconductor layers in the bottom structure by using the release protection layer as a mask, forming the plurality of bottom gaps, and forming the bottom gate in the plurality of bottom gaps.

In an embodiment, before forming the bottom gate in the plurality of bottom gaps, the method further includes:
forming second-type work function layers in the plurality of bottom gaps.

In an embodiment, the method further includes:
removing the release protection layer.

In an embodiment, before forming the top gate in the plurality of formed top gaps, the method further includes:
forming first-type work function layers in the plurality of formed top gaps.

In an embodiment, when forming the second-type work function layers in the plurality of bottom gaps, the second-type work function layers also cover the top structure,
where before removing the release protection layer, the method further includes:
removing the second-type work function layers covering the top structure.

In an embodiment, before forming the second-type work function layers in the plurality of bottom gaps, the method further includes:
forming high-κ dielectric layers in the plurality of bottom gaps and at a surface of the top structure,
where forming the second-type work function layers in the plurality of bottom gaps includes:
forming the second-type work function layers at surfaces of the high-κ dielectric layers; and
where removing the second-type work function layers covering the top structure includes:
removing the high-κ dielectric layers covering the top structure and the second-type work function layers covering the top structure.

In an embodiment, the first semiconductor layers of the bottom structure and the first semiconductor layers of the top structure are made of a same material, the second semiconductor layers of the bottom structure and the second semiconductor layers of the top structure are made of a same material, the first semiconductor layers are made of silicon germanium, and the second semiconductor layers are made of silicon,
where removing the first semiconductor layers in the bottom structure to form the plurality of bottom gaps, and forming the bottom gate in the bottom gaps includes:
removing the silicon germanium of the bottom structure, and forming the bottom gate in the bottom gaps formed between the plurality of silicons; and
where removing the first semiconductor layers in the top structure to form the plurality of top gaps, and forming the top gate in the top gaps includes:
removing the silicon germanium of the top structure, and forming the top gate in the top gaps formed between the plurality of silicons.

In an embodiment, the first semiconductor layers of the bottom structure are made of a material different from that of the first semiconductor layers of the top structure, the second semiconductor layers of the bottom structure are made of a material different from that of the second semiconductor layers of the top structure, the first semiconductor layers of the bottom structure are made of silicon, the second semiconductor layers of the bottom structure are made of silicon germanium, the first semiconductor layers of the top structure are made of silicon germanium, and the second semiconductor layers of the top structure are made of silicon,
where removing the first semiconductor layers in the bottom structure to form the plurality of bottom gaps, and forming the bottom gate in the bottom gaps includes:
removing the silicon of the bottom structure, and forming the bottom gate in the bottom gaps formed between the plurality of silicon germaniums; and
where removing the first semiconductor layers in the top structure to form the plurality of top gaps, and forming the top gate in the top gaps includes:
removing the silicon germanium of the top structure, and forming the top gate in the top gaps formed between the plurality of silicons.

In an embodiment, the release protection layer is made of one or more of SiO₂, SiNₓ, HfO₂, AlOₓ, LaOₓ, SiNO, SiCO, SiCNO and SiCN.

In an embodiment, a thickness of the release protection layer ranges from 0.1 nm to 100 nm.

The present disclosure provides a method for manufacturing a complementary field-effect transistor, including: providing a substrate; forming a nanosheet stacking structure at the substrate, where the nanosheet stacking structure includes a bottom structure located below an intermediate isolation layer and a top structure located above the intermediate isolation layer, and the top structure and the bottom structure are each formed by alternately stacking first semiconductor layers and second semiconductor layers; forming a bottom source and a bottom drain at both sides of the bottom structure, and forming a top source and a top drain at both sides of the top structure; removing first semiconductor layers in the bottom structure, and forming a bottom gate in a plurality of formed bottom gaps; and removing first semiconductor layers in the top structure, and forming a top gate in a plurality of formed top gaps.

### BRIEF DESCRIPTION OF THE DRAWINGS

In order to more clearly illustrate technical solutions in embodiments of the present disclosure, the drawings required for the description of the embodiments would be briefly introduced below. The drawings described below are some embodiments of the present disclosure. For those of ordinary skill in the art, other drawings may be obtained based on these drawings without any creative effort.

FIG. 1 shows a schematic flowchart of a method for manufacturing a complementary field-effect transistor according to an embodiment of the present disclosure;

FIG. 2 shows a schematic diagram of a three-dimensional structure of a complementary field-effect transistor according to an embodiment of the present disclosure; and

FIG. 3A to FIG. 20B show schematic structural diagrams of a complementary field-effect transistor manufactured by a method for manufacturing a complementary field-effect transistor according to an embodiment of the present disclosure.

### DETAILED DESCRIPTION OF EMBODIMENTS

In order to enable those skilled in the art to better understand solutions of the present disclosure, technical solutions in the embodiments of the present disclosure would be clearly and completely described below in conjunction with drawings in the embodiments of the present disclosure. The described embodiments are only part of the embodiments of the present disclosure, not all of the embodiments. Based on the embodiments in the present disclosure, any other embodiments obtained by those of ordinary skill in the art without creative work fall within the scope of protection of the present disclosure.

Although many specific details are set forth in the following description to facilitate a full understanding of the present disclosure, the present disclosure may be implemented in other ways different from those described herein, and those skilled in the art may make similar generalizations without violating the connotation of the present disclosure. Therefore, the present disclosure is not limited to the specific embodiments disclosed below.

Secondly, the present disclosure is described in detail with reference to the schematic diagram. When describing the embodiments of the present disclosure in detail, to facilitate description, the cross-sectional diagrams showing the device structure will not be partially enlarged according to the general scale, and the schematic diagrams are only examples, which should not limit the protection scope of the present disclosure. In addition, in actual production, three-dimensional dimensions of length, width and depth should be included.

Currently, in a procedure of manufacturing a complementary field-effect transistor, after top nanosheets and bottom nanosheets are released simultaneously, P-type work function layers are formed around all the nanosheets, and then a gate is deposited around the bottom nanosheets. P-type work function layers at surfaces of the top nanosheets not surrounded by the gate are selectively removed, and N-type work function layers are deposited at the surfaces of the top nanosheets. In this way, the top nanosheets and the bottom nanosheets are surrounded by different types of work function layers, and the complementary field-effect transistor is finally formed.

However, this manufacturing procedure has high requirements for a removal process of the P-type work function layers, and it is inclined to damage surfaces of the nanosheets when removing the P-type work function layer, which leads to a problem of channel interface.

Based on this, the present disclosure provides a method for manufacturing a complementary field-effect transistor, including: providing a substrate; forming a nanosheet stacking structure at the substrate, where the nanosheet stacking structure includes a bottom structure located below an intermediate isolation layer and a top structure located above the intermediate isolation layer, and the top structure and the bottom structure are each formed by alternately stacking first semiconductor layers and second semiconductor layers; forming a bottom source and a bottom drain at both sides of the bottom structure, and forming a top source and a top drain at both sides of the top structure; removing first semiconductor layers in the bottom structure, and forming a bottom gate in a plurality of formed bottom to-be-filled gaps; and removing first semiconductor layers in the top structure, and forming a top gate in a plurality of formed top to-be-filled gaps. That is, channel release is performed on the top structure and the bottom structure step by step, to facilitate that the formation of work function layers of the top structure and the formation of work function layers of the bottom structure do not affect each other, thereby avoiding the problem of channel interface and improving the performance of the manufactured complementary field-effect transistor.

In order to better understand technical solutions and technical effects of the present disclosure, specific embodiments would be described in detail below with reference to the accompanying drawings.

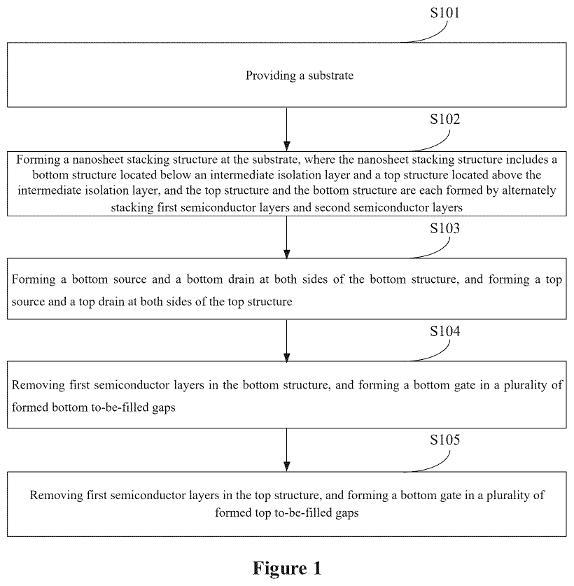

Referring to FIG. 1, FIG. 1 is a schematic flowchart of a method for manufacturing a complementary field-effect transistor according to an embodiment of the present disclosure.

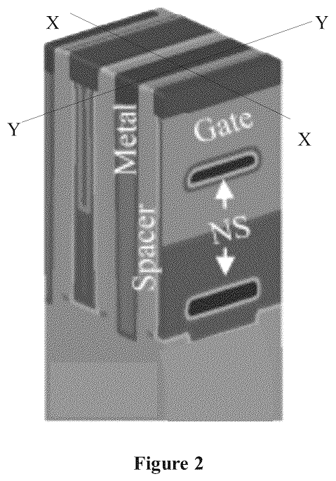

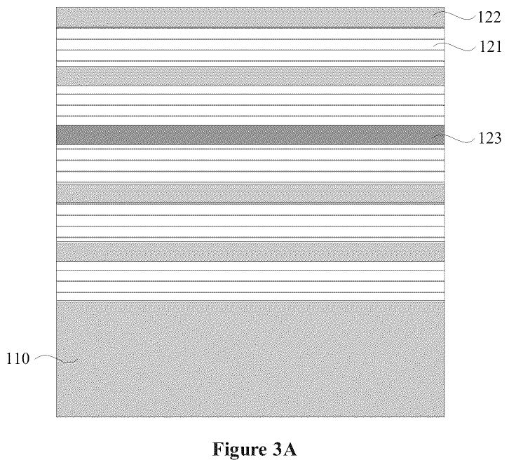

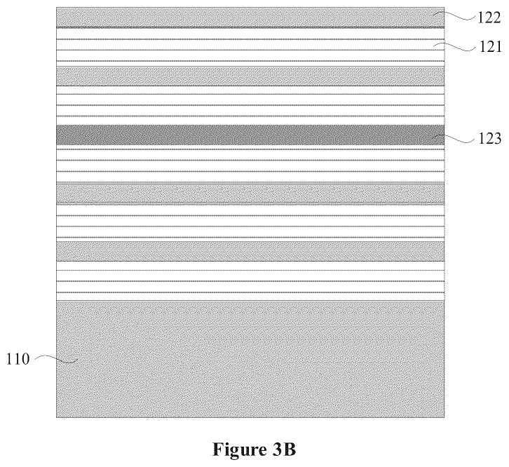

FIG. 2 shows a schematic diagram of a three-dimensional structure of a complementary field-effect transistor according to an embodiment of the present disclosure. Schematic cross-sectional diagrams in FIG. 3A to FIG. 20A and FIG. 3B to FIG. 20B are obtained by cross-sections of the schematic diagram of the three-dimensional structure in a XX direction and a YY direction respectively.

The method for manufacturing a semiconductor device provided by an embodiment of the present disclosure includes the following steps.

In S101, a substrate is provided.

In an embodiment of the present disclosure, a substrate 110 may be a semiconductor substrate, such as a bulk silicon substrate, and the substrate 110 may be doped to obtain a P-type semiconductor substrate or an N-type semiconductor substrate, such as a P-type silicon substrate or an N-type silicon substrate.

As an example, impurities may be injected into the bulk silicon substrate, and a highly doped well region is formed after annealing, to achieve a desired well depth. For different device types, the doping type of the substrate 110 is different. For a P-type semiconductor device, the highly doped well region is an N-well, and the injected impurities are n-type impurity ions, such as phosphorus (P) ions. For an N-type semiconductor device, the highly doped well region is a p-well, and the injected impurities are p-type impurity ions, such as boron (B) ions.

In S102, a nanosheet stacking structure is formed at the substrate, where the nanosheet stacking structure includes a bottom structure located below an intermediate isolation layer and a top structure located above the intermediate isolation layer, and the top structure and the bottom structure are each formed by alternately stacking first semiconductor layers and second semiconductor layers.

In an embodiment of the present disclosure, a nanosheet stacking structure may be formed at the substrate 110. The nanosheet stacking structure includes a bottom structure 520 located below an intermediate isolation layer 200 and a top structure 510 located above the intermediate isolation layer 200. The top structure 510 and the bottom structure 520 are each formed by alternately stacking first semiconductor layers 121 and second semiconductor layers 122.

A specific process flow is as follows: firstly, a stacked structure consisting of alternately stacked first semiconductor layers 121 and second semiconductor layers 122 may be formed at a side of the substrate 110, as shown in FIG. 3A and FIG. 3B.

In an embodiment, for different device types, the first semiconductor layers 121 may be made of a same material, and the second semiconductor layers 122 may be made of a same material. For example, for different device types, the first semiconductor layers 121 may be made of silicon germanium, and the second semiconductor layers 122 may be made of silicon or germanium. For different device types, the first semiconductor layers 121 may be made of different materials, and the second semiconductor layers 122 may also be made of different materials. For example, for a P-type semiconductor device, the first semiconductor layers 121 may be made of silicon, and the second semiconductor layers 122 may be made of silicon germanium. For an N-type semiconductor device, the first semiconductor layers 121 may be made of silicon germanium, and the second semiconductor layers 122 may be made of silicon.

Considering that the stacked structure may be used to form two transistors of different device types stacked up and down in subsequent steps, in a case that the material is silicon, silicon of different doping types may be used. For example, the second semiconductor layers 122 located at the top structure 510 are made of P-type doped silicon, and the second semiconductor layers 122 located at the bottom structure 520 may be made of N-type doped silicon.

Along a direction perpendicular to a plane where the substrate 110 is located, the stacked structure includes a buffer layer 123 located in a middle region. The buffer layer 123 is used to separate two formed transistors of different doping types that are stacked up and down in subsequent steps. The buffer layer 123 and the first semiconductor layers 121 may be made of a same material, and a thickness of the buffer layer 123 may be slightly greater than a thickness of the first semiconductor layers 121.

As a possible implementation, along the direction perpendicular to the plane where the substrate 110 is located, for different device types, the first semiconductor layers 121 may be made of a same material, and the second semiconductor layers 122 may be made of a same material. If the first semiconductor layers 121 are made of silicon germanium, the proportion of Ge in the first semiconductor layers 121 in the stacked structure gradually increases and then decreases, where the proportion of Ge in the buffer layer 123 is the highest. As an example, the proportion of Ge increases from 30% to 60% and then decreases to 30%.

In practical applications, silicon oxide may be formed at the substrate 110. The stacked structure may be formed after the silicon oxide at the substrate 110 is removed and the substrate 110 is cleaned.

In an embodiment of the present disclosure, a fin structure is formed by etching o the stacked structure and partial-thickness etching of the substrate 110. The fin structure includes the top structure 510, the bottom structure 520 and the substrate structure 530. The top structure 510 and the bottom structure 520 are separated by the buffer layer 123.

A process flow of forming the fin structure is introduced in detail below.

In S102a, a spacer transfer process is performed.

In an embodiment of the present disclosure, a first spacer is formed by using a self-aligned spacer transfer process. The first spacer is made of silicon nitride. A specific formation process is: a sacrificial layer is covered on the stacked structure, where the sacrificial layer may be made of polycrystalline silicon or amorphous silicon, part of the sacrificial layer is patterned and etched away by using photolithography, silicon nitride material is deposited, and the remaining sacrificial layer is then etched away by using anisotropic etching, so that only the first spacer is remained on the stacked structure. The first spacer acts as a hard mask in a subsequent photolithography for forming the fin.

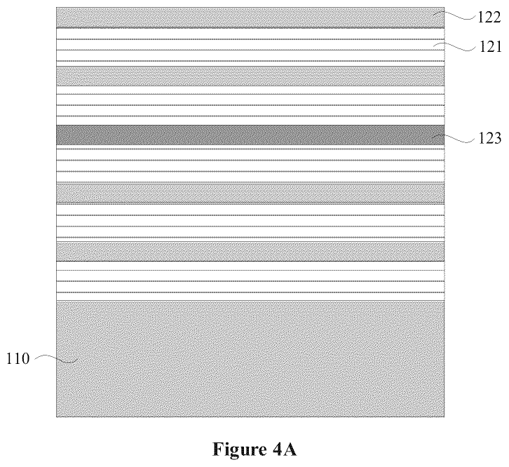

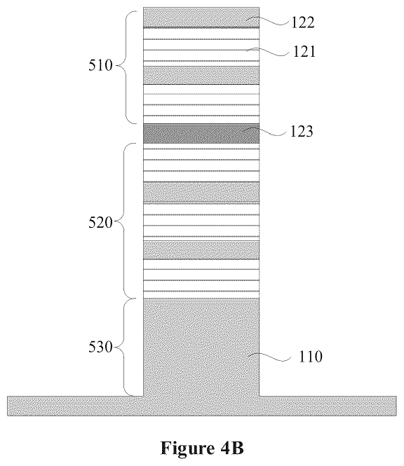

In S102b, the fin structure is formed, as shown in FIG. 4A and FIG. 4B.

In an embodiment of the present disclosure, a plurality of periodically distributed fins are formed by the etching of the stacked structure and the partial-thickness etching of the substrate 110, as shown in FIG. 4A and FIG. 4B. Etching is performed by using the first spacer as a mask, and a fin with a stacked structure is formed. A top part of the fin is the top structure 510 and the bottom structure 520 formed by the stacked structure. The top structure 510 and the bottom structure 520 are separated by the buffer layer 123, and the top structure 510 and the bottom structure 520 are channel regions. A bottom part of the fin is the substrate 110, and the fin as shown in FIG. 4B is formed. The fin includes not only the stacked structure, but also a single crystal silicon structure that penetrates into the substrate 110. The etching process may be dry etching or wet etching, and reactive ion etching may be used in an embodiment. The fin structure would be used to form nanosheets of the complementary field-effect transistor. Although FIG. 4B shows one fin, it should be understood that any suitable number and form of fins may be used in practical applications.

In practical applications, after the fin structure is formed, the first spacer may be removed.

In an embodiment of the present disclosure, in order to avoid damage on surfaces of nanosheets caused in a procedure of removing P-type work function layers of the top structure, where the P-type work function layers are formed at surfaces of all the nanosheets after the channel is released, a release protection layer 600 may be formed at a sidewall of the top structure along a first direction before the channel is released. By using the release protection layer 600, the channel release of the top structure is performed after the channel release of the bottom structure, and nanosheets of the top structure would not be affected when the P-type work function layers are formed at surfaces of nanosheets of the bottom structure, to avoid the damage on surfaces of the nanosheets caused by removing the P-type work function layers of the top structure, thereby improving the interface performance of the nanosheets of the top structure.

In an embodiment, the first direction is a direction of a fin line, and the first direction is perpendicular to a direction of connecting a top source region and a top drain region, that is, the first direction is the YY direction.

A process flow of forming the release protection layer is specifically introduced below.

In S102c, a first dielectric layer covering the fin structure is formed.

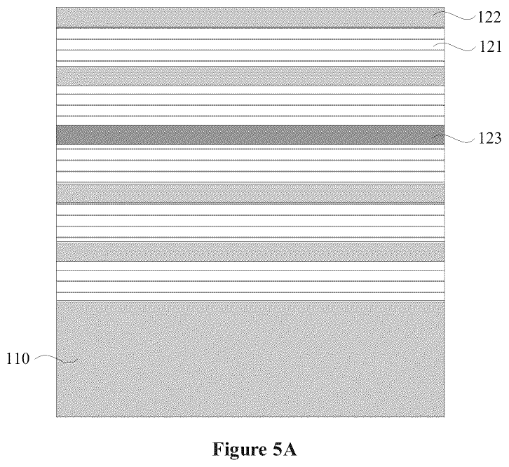

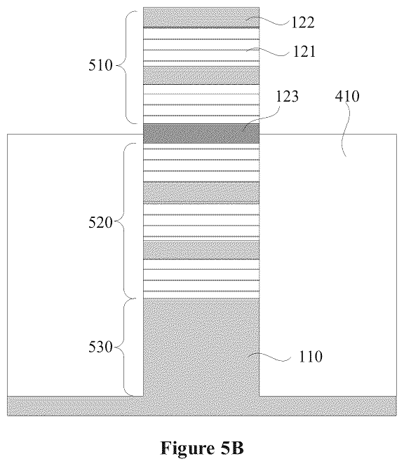

In an embodiment of the present disclosure, an insulating material is deposited to from a first dielectric layer 410 covering the fin structure, and a selective etch back process is performed on the first dielectric layer 410 to expose the top structure 510, as shown in FIG. 5A and FIG. 5B. In an embodiment, the first dielectric layer 410 is etched to be flush with a surface of the buffer layer 123, and at this time, the first dielectric layer 410 surrounds the bottom structure 520 and the substrate structure 530.

As a possible implementation, the first dielectric layer 410 is etched back to a position of ½ of the buffer layer 123.

In S102d, the release protection layer is formed.

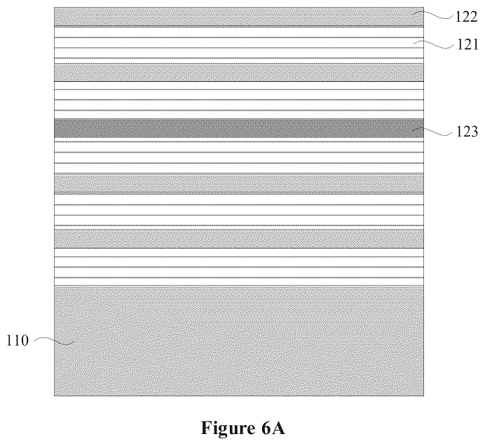

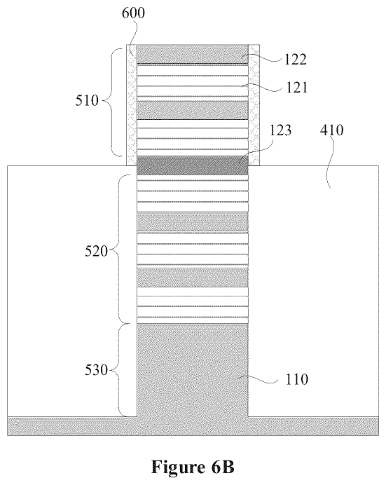

In an embodiment of the present disclosure, the release protection layer 600 is formed at a sidewall of the top structure 510 along the first direction, as shown in FIG. 6A and FIG. 6B.

In an embodiment, the release protection layer 600 is made of one or more of SiO₂, SiNₓ, HfO₂, AlOₓ, LaOₓ, SiNO, SiCO, SiCNO and SiCN. A thickness of the release protection layer 600 ranges from 0.1 nm to 100 nm.

In S102e, a shallow trench isolation is formed.

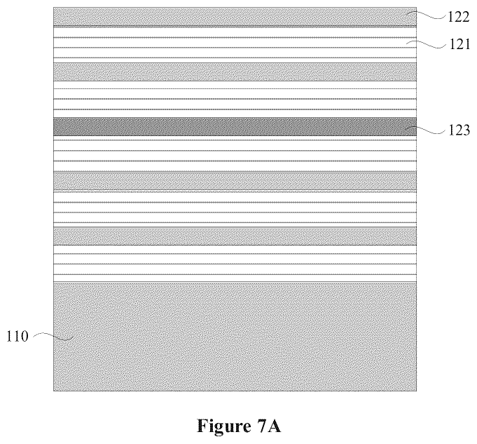

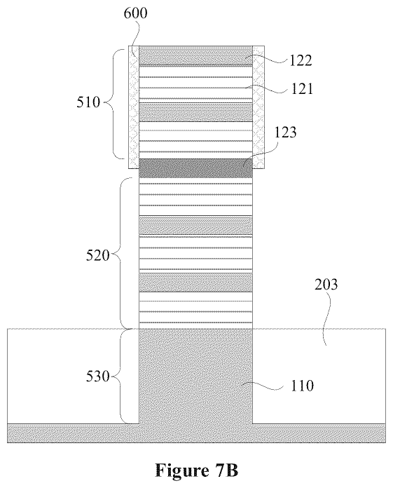

In an embodiment of the present disclosure, a shallow trench isolation (STI) 203 may be formed between different fins, as shown in FIG. 7A and FIG. 7B.

In an embodiment, a selective etch back process is performed on the first dielectric layer 410 formed in S102c, to expose three-dimensional fins. In an embodiment, the first dielectric layer 410 is etched to be flush with a bottom surface of the bottom structure 520, and the top structure 510 and the bottom structure 520 are exposed, thereby forming the shallow trench isolation 203 adjacent to the fin structure. A surface of the shallow trench isolation 203 at a side away from the substrate 110 may be flush with a surface of the stacked structure in the fin structure at a side close to the substrate 110, or may be higher or lower than the surface of the stacked structure in the fin structure at the side close to the substrate 110. The shallow trench isolation 203 may be formed by a suitable dielectric material, such as silicon dioxide or silicon nitride. A function of the shallow trench isolation 203 is to separate channels on adjacent fin structures.

In an embodiment of the present disclosure, considering that two transistors of different doping types stacked up and down need to be formed subsequently, sources and drains of the two transistors need to be formed separately. Source regions and drain regions of the two transistors need to be formed firstly, and then inner spacers are formed. A specific process is described in detail below.

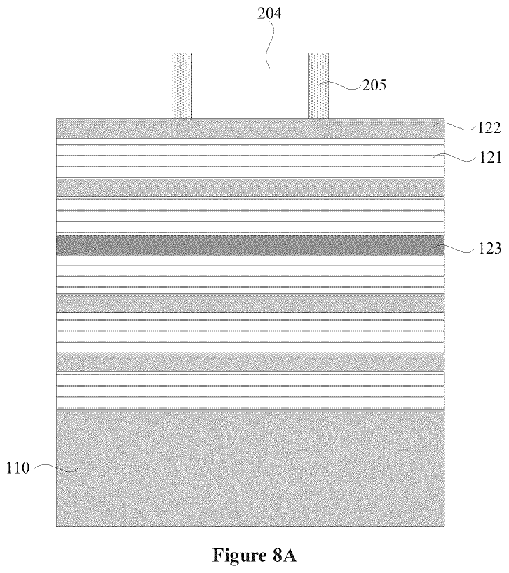

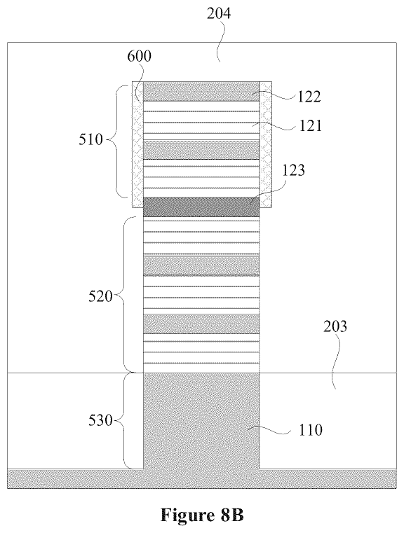

In S102f, a dummy gate and second spacers are formed, as shown in FIG. 8A and FIG. 8B.

In an embodiment of the present disclosure, a dummy gate stack is formed at the exposed fin structure. The dummy gate stack is a multi-layer structure, including a gate insulating dielectric layer (not shown), a dummy gate 204 and a hard mask layer (not shown). The dummy gate stack may be formed by processes such as thermal oxidation, chemical vapor deposition, and sputtering. The dummy gate stack spans the stacked structure at an upper part of the fin structure, and a plurality of dummy gates are periodically distributed along a direction of the fin line. The dummy gate 204 may be made of polycrystalline silicon or amorphous silicon. The hard mask layer may be made of oxide, carbide, organic matter, etc.

In an embodiment of the present disclosure, second spacers 205 may be respectively provided at both sides of the dummy gate stack, and the second spacers 205 at both sides have a same thickness. The second spacers 205 may be made of a dielectric material with isolation properties, such as silicon nitride or doped silicon oxide.

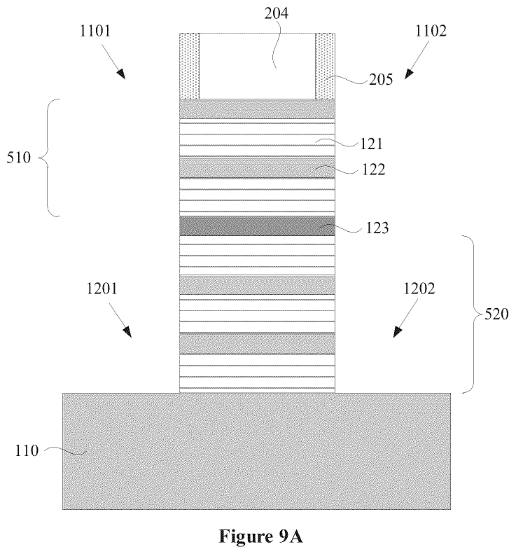

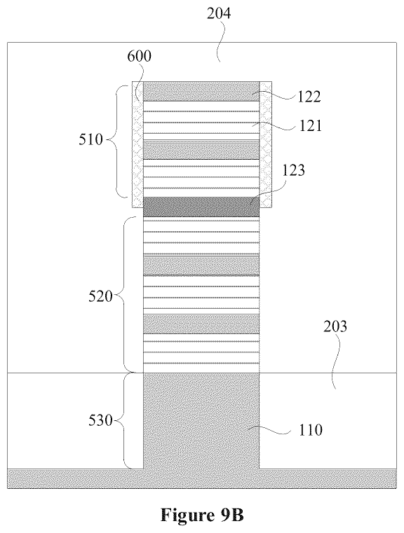

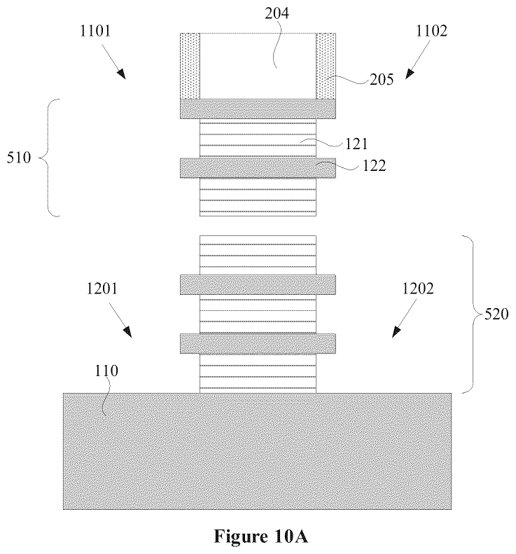

In S102g, the top structure, the buffer layer and the bottom structure are etched, and a top source region, a top drain region, a bottom source region and a bottom drain region are formed, as shown in FIG. 9A and FIG. 9B.

In an embodiment of the present disclosure, after forming the dummy gate 204 and the second spacers 205, the dummy gate 204 and the second spacers 205 may be used as a mask to perform source and drain etching on the stacked structure through an etching process. In an embodiment, source and drain etching is performed on the top structure 510, the buffer layer 123 and the bottom structure 520 in a second direction to form a top source region 1101, a top drain region 1102, a bottom source region 1201 and a bottom drain region 1202. A top channel region is between the top source region 1101 and the top drain region 1102, and a bottom channel region is between the bottom source region 1201 and the bottom drain region 1202. The first direction is perpendicular to the second direction, and the second direction is a direction of connecting the top source region 1101 and the top drain region 1102. The top source region 1101, the top drain region 1102, the bottom source region 1201 and the bottom drain region 1202 no longer form a stacked structure after the etching, as shown in FIG. 9A.

In S102h, a concave structure is formed.

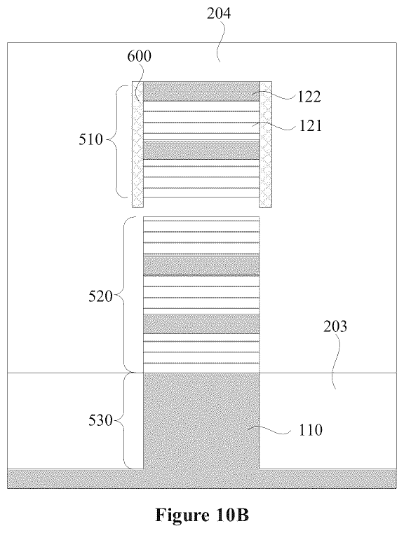

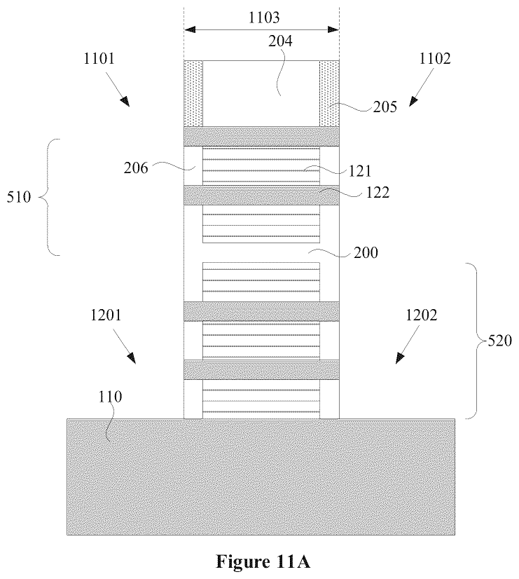

In an embodiment of the present disclosure, selective etching is performed on the first semiconductor layers 121 located in the top structure 510 and the bottom structure 520 along the second direction, that is, part of the first semiconductor layers 121 at a sidewall of the top structure 510 and a sidewall of the bottom structure 520 are etched away, and the second semiconductor layers 122 are not damaged. Along the second direction, the concave structure is formed at a position where the first semiconductor layers 121 are missing compared with the second semiconductor layers 122, that is, pull-back etching is performed, and part of the first semiconductor layers 121 are etched away from the bottom source region 1201 and the bottom drain region 1202 to the bottom channel region 1203, and from the top source region 1101 and the top drain region 1102 to the top channel region 1103, as shown in FIG. 10A and FIG. 10B.

While selective etching is performed on the first semiconductor layers 121 in the top structure 510 and the bottom structure 520, the buffer layer 123 is also etched away to form a buffer isolation structure, as shown in FIG. 10A and FIG. 10B.

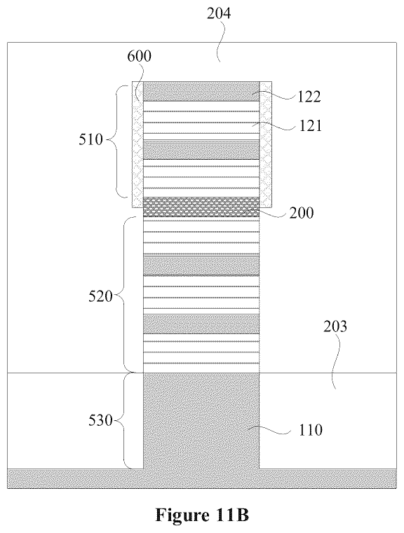

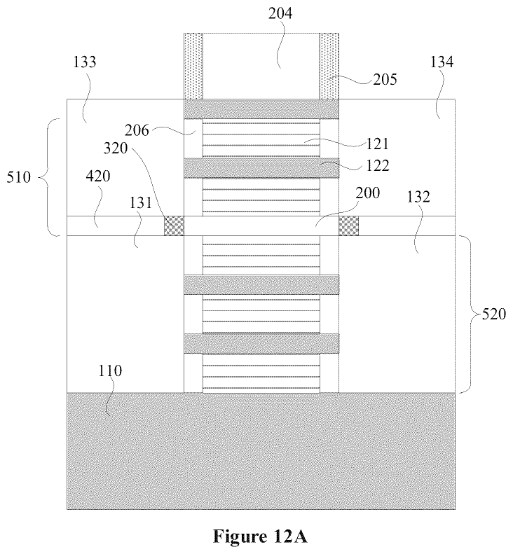

In S102i, inner spacers are formed, as shown in FIG. 11A and FIG. 11B.

In an embodiment of the present disclosure, after the etching on the first semiconductor layers 121 is finished, a dielectric material is deposited at the bottom structure 520 located at the bottom channel region and the top structure 510 located at the top channel region, i.e., a periphery of the fin, and the dielectric material is etched to form inner spacers 206. The inner spacers 206 are flush with the second semiconductor layers 122 in a direction perpendicular to a plane where the substrate 110 is located. In other words, the concave structure caused by etching in S102h is filled by the inner spacers 206. The inner spacers 206 may be made of silicon nitride or silicon oxide.

In addition to filling the concave structure, the dielectric material also fills the buffer isolation structure, thereby forming the intermediate isolation layer 200.

At this time, the bottom structure 520 is located below the intermediate isolation layer 200, and the top structure 510 is located above the intermediate isolation layer 200, thereby forming a nanosheet stacking structure including the top structure 510 and the bottom structure 520.

In S103, a bottom source and a bottom drain are formed at both sides of the bottom structure, and a top source and a top drain are formed at both sides of the top structure.

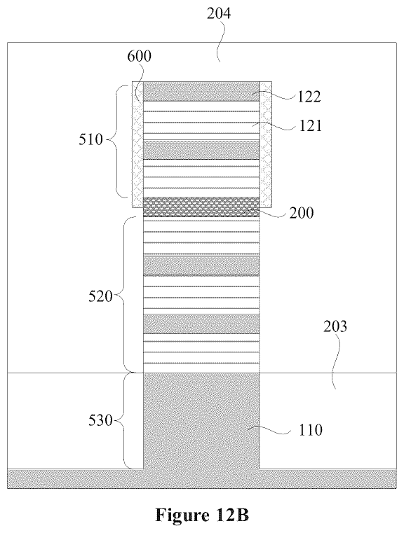

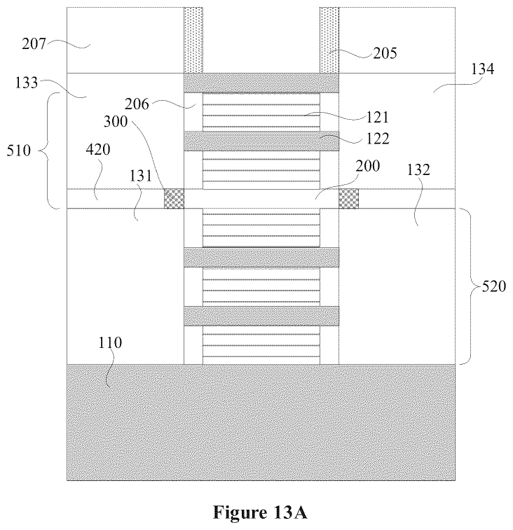

In an embodiment of the present disclosure, after etching the stacked structure to form the bottom source region 1201 and the bottom drain region 1202, a bottom source 131 and a bottom drain 132 may be formed at the bottom source region 1201 and the bottom drain region 1202 respectively, that is, the bottom source 131 and the bottom drain 132 are formed at both sides of the bottom structure 520, as shown in FIG. 12A and FIG. 12B. Surfaces of the bottom source 131 and the bottom drain 132 at sides away from the substrate 110 may be flush with a surface of the intermediate isolation layer 200 at a side close to the substrate 110.

In an embodiment, for different types of semiconductor devices, source materials and drain materials may be different. For a P-type semiconductor device, a source and drain material is boron-doped silicon germanium, i.e., SiGe:B. For a N-type semiconductor device, a source and drain material is carbon-doped silicon, i.e., Si:C.

In an embodiment of the present disclosure, before forming the bottom source 131 and the bottom drain 132, target spacers 320 are formed by deposition and etching. The target spacers 320 are at least located at a sidewall of a top channel structure, so as to achieve isolation at the top channel structure, that is, the target spacers 320 are respectively provided at both sides of the top channel structure, and the target spacers 320 at both sides have a same thickness. The target spacers 320 may be made of a dielectric material with isolation properties, such as silicon nitride or doped silicon oxide.

In an embodiment of the present disclosure, after forming the target spacers 320, the bottom source 131 and the bottom drain 132 may be formed at the bottom source region 1201 and the bottom drain region 1202 respectively, a dielectric material is then deposited, a planarization process is performed, and a first dielectric layer 420 is formed. The first dielectric layer 420 covers the top structure 510 and the target spacers 320. The first dielectric layer 420 may be etched back to a surface of the intermediate isolation layer 200 at a side away from the substrate 110, and the target spacers 320 may be also etched to the surface of the intermediate isolation layer 200 at the side away from the substrate 110, that is, the first dielectric layer 420 and the target spacers 320 are both etched to the intermediate isolation layer 200, thereby isolating the source from the drain in both the upper and lower transistors.

In an embodiment of the present disclosure, after etching back the first dielectric layer 420 and the target spacers 320, a top source 133 and a top drain 134 may be further formed at the first dielectric layer 420 and the target spacers 320, that is, the top source 133 and the top drain 134 may be formed at both sides of the top structure 510, so as to form the source and drain of a top transistor of the two transistors stacked up and down, as shown in FIG. 12A. The top source 133 and the top drain 134 may be specifically located at the first dielectric layer 420.

In S104, first semiconductor layers in the bottom structure are removed, and a bottom gate is formed in a plurality of formed bottom to-be-filled gaps.

In an embodiment of the present disclosure, channel release may be firstly performed on the bottom structure 520, that is, the first semiconductor layers 121 in the bottom structure 520 are removed, and a bottom gate 161 is formed in a plurality of formed bottom to-be-filled gaps 402.

Before removing the first semiconductor layers 121 in the bottom channel region, the dummy gate 204 may be removed first. A specific process flow is as follows.

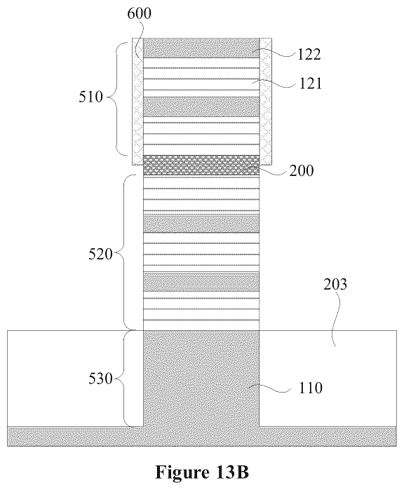

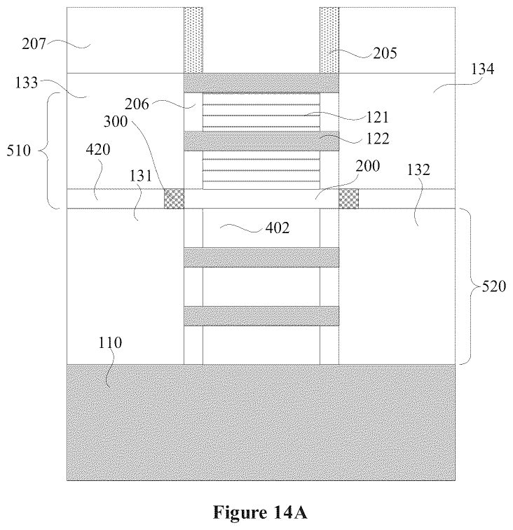

In S104a, the dummy gate 204 is removed, as shown in FIG. 13A and FIG. 13B.

In an embodiment of the present disclosure, an isolation layer 207 may be deposited at surfaces of the dummy gate 204, the top source 133 and the top drain 134 to prevent an interconnection short circuit between the dummy gate 204 and the top source 133 or the top drain 134 in subsequent steps, and a chemical mechanical polishing process is performed on the isolation layer 207 for planarization. Then, as shown in FIG. 13A and FIG. 13B, the dummy gate 204 formed by polycrystalline silicon or amorphous silicon is etched or corroded through a selective etching or corrosion process, that is, the dummy gate 204 is removed.

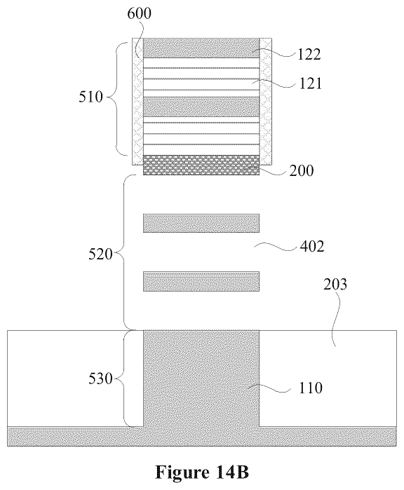

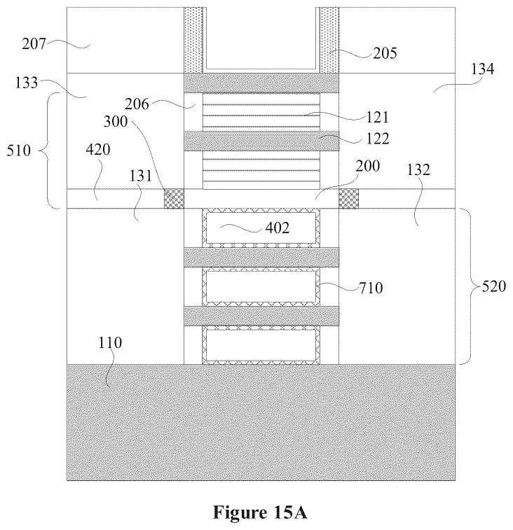

In an embodiment of the present disclosure, the first semiconductor layers 121 in the bottom channel region may be removed by using the release protection layer 600 as a mask, that is, a nanosheet channel release procedure is performed at the bottom channel region, so as to form the plurality of bottom to-be-filled gaps 402 between the second semiconductor layers 122 in the bottom channel region, as shown in FIG. 14A and FIG. 14B.

In an embodiment, the first semiconductor layers 121 in the stacked structure located at the bottom channel region may be selectively etched by using the release protection layer 600 as a mask, and nanosheet channel release is performed at the bottom channel region. In other words, a bottom structure exposed by the fin is processed, and each of the first semiconductor layers 121 in the bottom channel region is removed. The first semiconductor layers 121 are sacrificial layers, and nanosheets formed by the second semiconductor layers 122 are released. Since the release protection layer 600 covering the top structure 510 is formed in a direction perpendicular to a direction of connecting the source and the drain, the release protection layer 600 may realize that the top structure 510 is not affected when channel release is performed on the bottom structure 520.

In an embodiment of the present disclosure, after forming the plurality of bottom to-be-filled gaps 402, interface layers may be formed at surfaces of the second semiconductor layers 122, and interfaces between the interface layers and the second semiconductor layers 122 may be passivated. In an embodiment, the interface layer may be made of silicon oxide.

In an embodiment of the present disclosure, after forming the interface layers, high-κ dielectric layers may also be formed at surfaces of the interface layers. The high-κ dielectric layers surround the surfaces of the interface layers. In an embodiment, the high-κ dielectric layers may be made of one of HfO₂, HfSiOₓ, HfON, HfSiON, HfAlOₓ, HfLaOₓ, Al₂O₃, ZrO₂, ZrSiOₓ, Ta₂O₅, or La₂O₃ or any combination thereof.

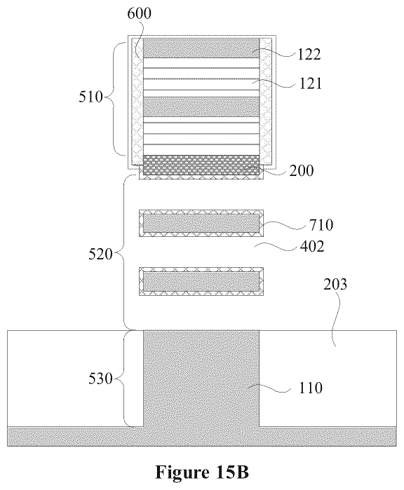

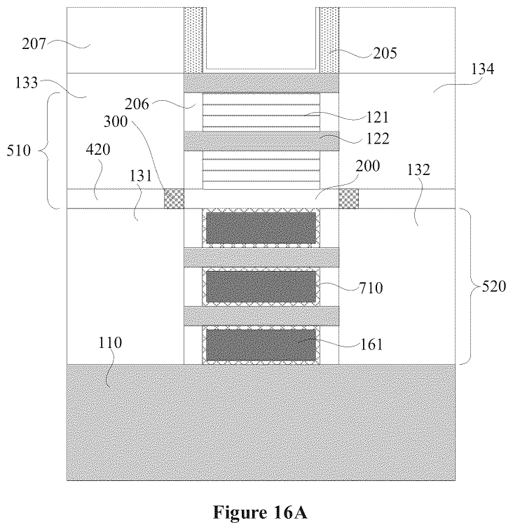

Considering that forming upper and lower transistors of different types needs to use the intermediate isolation layer 200 to isolate different types of transistors and use different types of work function layers for forming the different types of transistors, second-type work function layers 710 are formed at the plurality of bottom to-be-filled gaps 402 in the bottom channel region, and the second-type work function layers 710 surround surfaces of the high-κ dielectric layers. In an embodiment, the second-type work function layers 710 are P-type work function layers (P-WFLs), as shown in FIG. 15A and FIG. 15B.

When the interface layers, the high-κ dielectric layers and the second-type work function layers 710 are formed at the plurality of bottom to-be-filled gaps 402 in the bottom channel region, the interface layers, the high-κ dielectric layers and the second-type work function layers 710 further cover a surface of the top structure 510 at a side away from the substrate 110, a sidewall of the release protection layer 600 and the surface of the intermediate isolation layer 200 at the side close to the substrate 110, as shown in FIG. 15A and FIG. 15B.

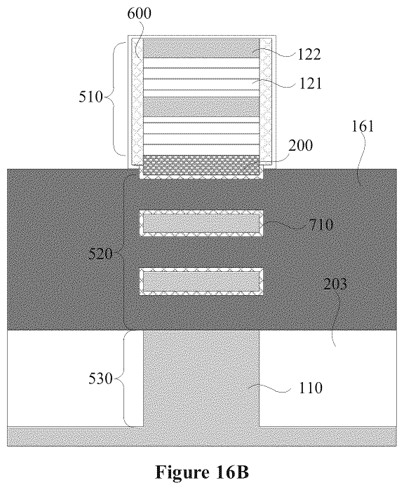

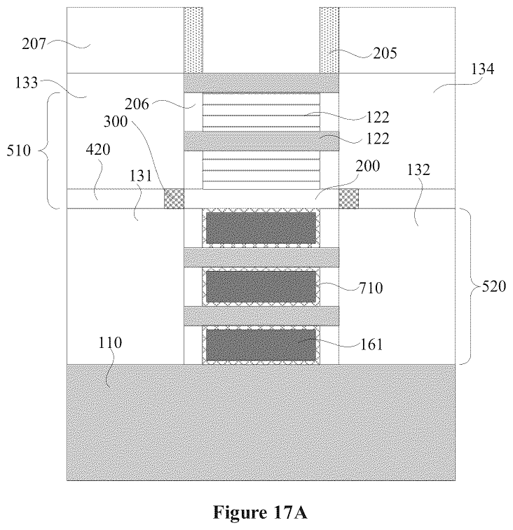

In an embodiment of the present disclosure, the plurality of bottom to-be-filled gaps 402 in the bottom channel region may be filled with a conductive material to form the bottom gate 161. In an embodiment, the conductive material is deposited to cover the fin structure, and then the conductive material is etched to a position of ½ of the intermediate isolation layer 200 to form the bottom gate 161, as shown in FIG. 16A and FIG. 16B.

After nanosheet channel release is performed at the bottom, there is the plurality of bottom to-be-filled gaps 402 between the plurality of second semiconductor layers 122. The plurality of bottom to-be-filled gaps 402 may be filled with the bottom gate 161, the bottom gate 161 surrounds the second semiconductor layers 122 to form a gate-all-around structure. In an embodiment, the bottom gate 161 surrounds the second-type work function layers 710. A stack composed of the plurality of second semiconductor layers 122 forms a bottom channel structure.

In an embodiment of the present disclosure, after the bottom gate 161 is formed a the plurality of bottom to-be-filled gaps 402 in the bottom channel region, a channel release of the bottom structure has been finished, and a channel release of the top structure may be performed.

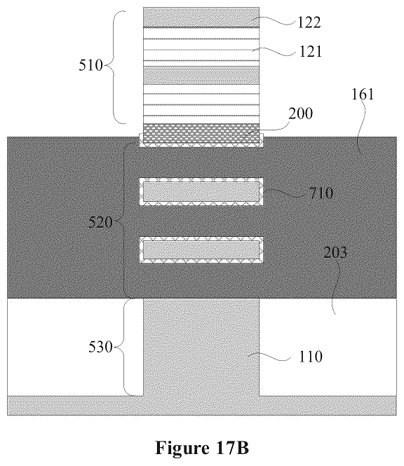

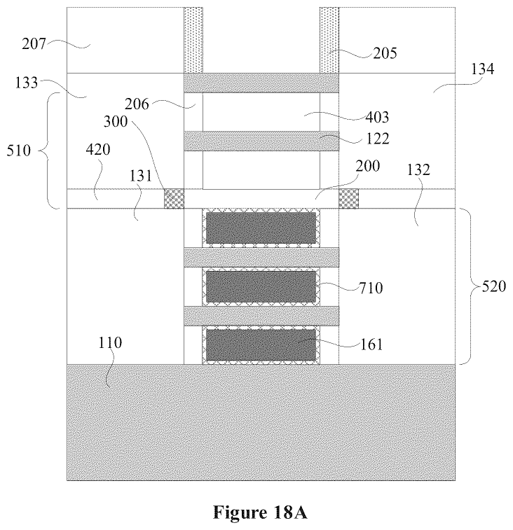

In an embodiment, the interface layers, the high-κ dielectric layers and the second-type work function layers 710 covering the top structure 510 and the sidewall of the release protection layer 600 may be removed first, and then the release protection layer 600 covering the sidewall of the top structure 510 may be removed, as shown in FIG. 17A and FIG. 17B.

In S105, the first semiconductor layers in the top structure are removed, and a bottom gate is formed in a plurality of formed top to-be-filled gaps.

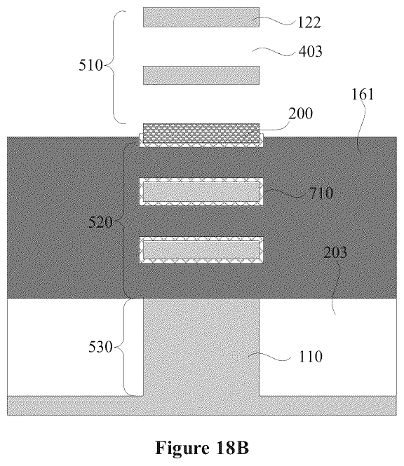

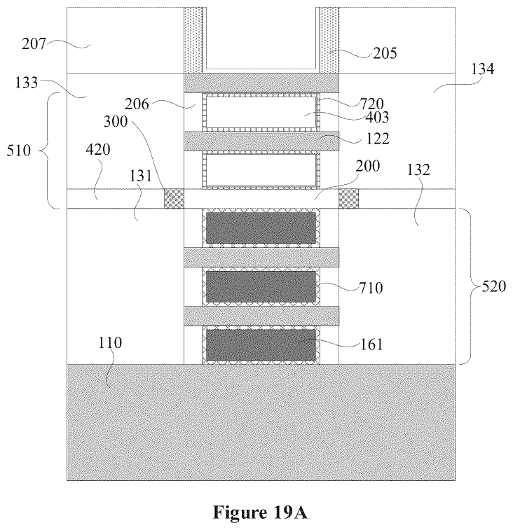

In an embodiment of the present disclosure, the first semiconductor layers 121 in the top channel region may be removed, that is, a nanosheet channel release process is performed at the top channel region to form a plurality of top to-be-filled gaps 403 between the second semiconductor layers 122 in the top channel region, as shown in FIG. 18A and FIG. 18B.

In an embodiment, the first semiconductor layers 121 in the stacked structure located at the top channel region may be selectively etched, and nanosheet channel release is performed at the top channel region. In other words, a top structure exposed by the fin is processed, and each of the first semiconductor layers 121 in the top channel region is removed. The first semiconductor layers 121 are sacrificial layers, and nanosheets formed by the second semiconductor layers 122 are released. Since the release protection layer 600 covering the top structure 510 is formed in the direction perpendicular to the direction of connecting the source and the drain, the release protection layer 600 may realize that the channel release of the top structure 510 is performed after the channel release of the bottom structure 520, and when channel release is performed on the top structure 510, the bottom gate 161 has been formed in the bottom structure 520, so the channel release of the top structure 510 would not affect the bottom structure 520.

In an embodiment of the present disclosure, after forming the plurality of top to-be-filled gaps 403, interface layers may be formed at the surfaces of the second semiconductor layers 122, and interfaces between the interface layers and the second semiconductor layers 122 may be passivated. After forming the interface layers, high-κ dielectric layers may be further formed at the surfaces of the interface layers.

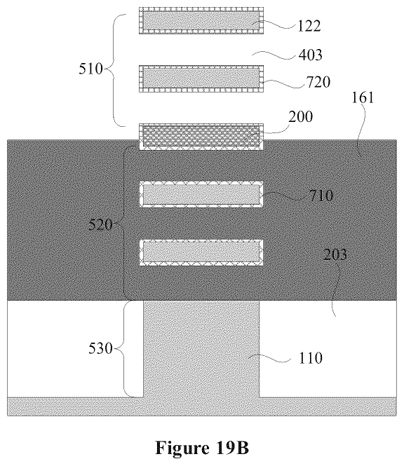

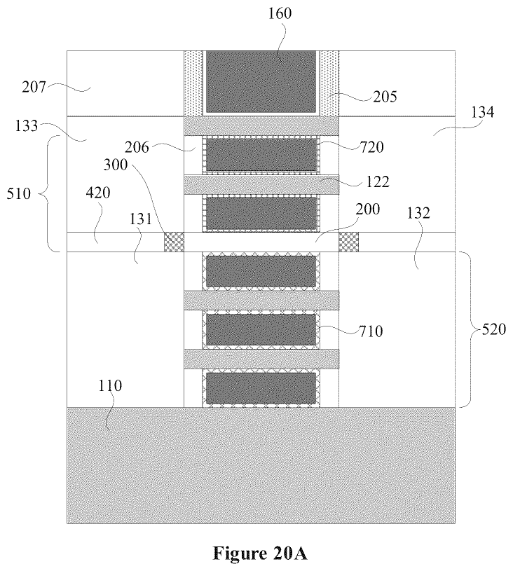

Considering that forming upper and lower transistors of different types needs to use the intermediate isolation layer 200 to isolate the different types of transistors and use different types of work function layers for forming the different types of transistors, first-type work function layers 720 are formed at the plurality of top to-be-filled gaps 403 in the top channel region, and the first-type work function layers 720 surround surfaces of the high-κ dielectric layers. In an embodiment, the first-type work function layers 720 are N-type work function layers (N-WFLs), as shown in FIG. 19A and FIG. 19B.

In an embodiment of the present disclosure, the complementary field-effect transistor includes two transistors of different device types stacked up and down, the first semiconductor layers 121 for different device types may be made of a same material, and the second semiconductor layers 122 for different device types may be made of a same material; or the first semiconductor layers 121 for different device types may be made of different materials, and the second semiconductor layers 122 for different device types may also be made of different materials. Therefore, when channel release of the bottom structure 520 and the top structure 510 is performed, materials subjected to selective removal may be different, which is described in detail below.

As a possible implementation, the first semiconductor layers 121 in the bottom channel region and the top channel region are made of a same material, the second semiconductor layers 122 in the bottom channel region and the top channel region are made of a same material, the first semiconductor layers 121 are made of silicon germanium, and the second semiconductor layers 122 are made of silicon. Forming the plurality of bottom to-be-filled gaps 402 by removing the first semiconductor layers 121 in the bottom channel region in S104 is to selectively remove the silicon germanium in the bottom channel region by using the release protection layer 600 as a mask, and the plurality of bottom to-be-filled gaps 402 are formed between the plurality of silicons. Forming the plurality of top to-be-filled gaps 403 by removing the first semiconductor layers 121 in the top channel region in S105 is to selectively remove the silicon germanium in the top channel region, and the plurality of top to-be-filled gaps 403 are formed between the plurality of silicons. In other words, a silicon-stack nanosheet stack device is formed. In a selective removal process, an etchant that exhibits a higher selective etching rate for silicon germanium relative to silicon may be used.

As another possible implementation, the first semiconductor layers 121 in the bottom channel region are made of material different from that of the first semiconductor layers 121 in the top channel region, the second semiconductor layers 122 in the bottom channel region are made of material different from that of the second semiconductor layers 122 in the top channel region, the first semiconductor layers 121 in the bottom channel region are made of silicon, the second semiconductor layers 122 in the bottom channel region are made of silicon germanium, the first semiconductor layers 121 in the top channel region are made of silicon germanium, and the second semiconductor layers 122 in the top channel region are made of silicon. Forming the plurality of bottom to-be-filled gaps 402 by removing the first semiconductor layers 121 in the bottom channel region in S104 is to selectively remove the silicon in the bottom channel region by using the release protection layer 600 as a mask, and the plurality of bottom to-be-filled gaps 402 are formed between the plurality of silicon germaniums. In the selective removal process, an etchant that exhibits a higher selective etching rate for silicon relative to silicon germanium may be used. Removing the first semiconductor layers 121 in the top channel region, and forming the plurality of top to-be-filled gaps 403 in S105 is to selectively remove the silicon germanium in the top channel region, and the plurality of top to-be-filled gaps 403 are formed between the plurality of silicons. In the selective removal process, an etchant that exhibits a higher selective etching rate for silicon germanium relative to silicon. At this time, a heterogeneous complementary field-effect transistor is formed, with a bottom channel structure being made of silicon germanium, and a top channel structure being made of silicon. The performance of a bottom transistor is improved.

In other words, for a channel of the top structure, a sacrificial layer made of a material different from that of the bottom structure may be selectively removed during secondary channel release based on the release protection layer, so as to form a heterogeneous channel device in which a top channel and a bottom channel are made of different semiconductor materials.

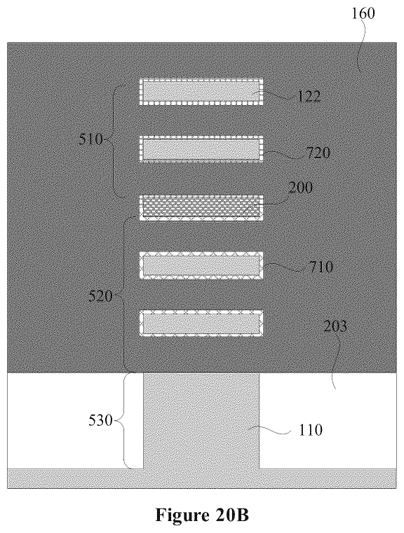

In an embodiment of the present disclosure, after nanosheet channel release is performed at the top, there is the plurality of top to-be-filled gaps 403 between the plurality of second semiconductor layers 122. The plurality of top to-be-filled gaps 403 may be filled with the top gate, and the top gate surrounds the second semiconductor layers 122 to form a gate-all-around structure. In an embodiment, the top gate surrounds the first-type work function layers 720. A stack composed of a plurality of second semiconductor layers 122 forms the top channel structure and the bottom channel structure, that is, a nanosheet channel of the complementary field-effect transistor is formed, as shown in FIG. 20A and FIG. 20B.

In practical applications, in addition to forming the top gate at the top to-be-filled gaps 403, the gate 160 also covers space after the isolation layer 207 and the dummy gate 204 are removed. The gate 160 covering the isolation layer 207 may be chemically mechanically polished for planarization. The gate 160 includes the top gate and the bottom gate 161.

In an embodiment of the present disclosure, after the gate 160 is formed, dielectric deposition may be performed at a top of the complementary field-effect transistor away from the substrate 110, and a top dielectric layer is formed. A contact hole is etched in the top dielectric layer until reaching a surface of the top source or the top drain, a metal material is deposited in the contact hole to form a contact electrode of the top source or the top drain, and then multi-layer back-end interconnection and passivation protection processes are completed.

It may be seen that the present disclosure provides a method for manufacturing a complementary field-effect transistor. The source and the drain are formed in the second direction, and the release protection layer is formed at the sidewall of the top structure in the first direction. The first semiconductor layers in the bottom channel region are removed by using the release protection layer as a mask, the plurality of bottom to-be-filled gaps are formed, and second-type work function layers are formed in the plurality of bottom to-be-filled gaps. The plurality of bottom to-be-filled gaps are filled with the bottom gate. The release protection layer is removed. The first semiconductor layers in the top channel region are removed, the plurality of top to-be-filled gaps are formed, and first-type work function layer are formed in the plurality of top to-be-filled gaps. The plurality of top to-be-filled gaps are filled with the top gate. That is, the step-by-step channel releases performed on the top structure and the bottom structure and the formation of the work function layers are realized by using the release protection layer. In other words, the release protection layer covering the top structure is formed in the direction perpendicular to the direction of connecting the source and the drain, and the release protection layer is used to realize that the channel release of the top structure is performed after the channel release of the bottom structure. Based on the release protection layer, the channel of the top structure would not be covered by the second-type work function layers in a channel-surrounding manner, thereby overcoming the difficulty in removing the second-type work function layers of the top structure, and avoiding damage to a channel surface when removing the second-type work function layers of the top structure. The work function layers of the top structure and the work function layers the bottom structure are formed separately and would not affect each other, thereby ensuring that the top structure still has a high-quality channel surface, avoiding a problem of channel interface, and improving the performance of the manufactured complementary field-effect transistor.

The structural embodiments described above are only illustrative, and those of ordinary skills in the art may understand and implement it without any creative effort.

The above are only preferred implementations of the present disclosure. Although the present disclosure is disclosed by referring to preferred embodiments, it is not intended to limit the present disclosure. Numerous modifications, variations and equivalent alternatives can be made by those skilled in the art based on the above disclosed method and technical contents without departing from the scope of the technical solutions. Therefore, any simple amendment, equivalent change or modification made to the above embodiments based on the technical essence of the present disclosure without departing from the content of the technical solutions of the present disclosure still falls within the protection scope of the technical solutions of the present disclosure.

1. A method for manufacturing a complementary field-effect transistor, comprising:
providing a substrate;
forming a nanosheet stacking structure at the substrate, wherein the nanosheet stacking structure comprises a bottom structure located below an intermediate isolation layer and a top structure located above the intermediate isolation layer, and the top structure and the bottom structure are each formed by alternately stacking first semiconductor layers and second semiconductor layers;
removing the first semiconductor layers in the bottom structure to form a plurality of bottom gaps;
forming a bottom gate in the plurality of bottom gaps;
removing the first semiconductor layers in the top structure to form a plurality of top gaps; and
forming a top gate in a plurality of formed top gaps,
wherein the step of removing the first semiconductor layers in the bottom structure is performed separately from the step of removing the first semiconductor layers in the top structure.

2. The method according to claim 1, further comprising:
forming a release protection layer at a sidewall of the top structure,
wherein removing the first semiconductor layers in the bottom structure to form the plurality of bottom gaps, and forming the bottom gate in the plurality of bottom gaps comprises:
removing the first semiconductor layers in the bottom structure by using the release protection layer as a mask, forming the plurality of bottom gaps, and forming the bottom gate in the plurality of bottom gaps.

3. The method according to claim 2, wherein before forming the bottom gate in the plurality of bottom gaps, the method further comprises:
forming second-type work function layers in the plurality of bottom gaps.

4. The method according to claim 3, further comprising:
removing the release protection layer.

5. The method according to claim 4, wherein before forming the top gate in the plurality of formed top gaps, the method further comprises:
forming first-type work function layers in the plurality of formed top gaps.

6. The method according to claim 4, wherein when forming the second-type work function layers in the plurality of bottom gaps, the second-type work function layers also cover the top structure,
wherein before removing the release protection layer, the method further comprises:
removing the second-type work function layers covering the top structure.

7. The method according to claim 6, wherein before forming the second-type work function layers in the plurality of bottom gaps, the method further comprises:
forming high-κ dielectric layers in the plurality of bottom gaps and at a surface of the top structure,
wherein forming the second-type work function layers in the plurality of bottom gaps comprises:
forming the second-type work function layers at surfaces of the high-κ dielectric layers; and
wherein removing the second-type work function layers covering the top structure comprises:
removing the high-κ dielectric layers covering the top structure and the second-type work function layers covering the top structure.

8. The method according to claim 1, wherein the first semiconductor layers of the bottom structure and the first semiconductor layers of the top structure are made of a same material, the second semiconductor layers of the bottom structure and the second semiconductor layers of the top structure are made of a same material, the first semiconductor layers are made of silicon germanium, and the second semiconductor layers are made of silicon,
wherein removing the first semiconductor layers in the bottom structure to form the plurality of bottom gaps, and forming the bottom gate in the bottom gaps comprises:
removing the silicon germanium of the bottom structure, and forming the bottom gate in the bottom gaps formed between the plurality of silicons; and
wherein removing the first semiconductor layers in the top structure to form the plurality of top gaps, and forming the top gate in the top gaps comprises:
removing the silicon germanium of the top structure, and forming the top gate in the top gaps formed between the plurality of silicons.

9. The method according to claim 1, wherein the first semiconductor layers of the bottom structure are made of a material different from that of the first semiconductor layers of the top structure, the second semiconductor layers of the bottom structure are made of a material different from that of the second semiconductor layers of the top structure, the first semiconductor layers of the bottom structure are made of silicon, the second semiconductor layers of the bottom structure are made of silicon germanium, the first semiconductor layers of the top structure are made of silicon germanium, and the second semiconductor layers of the top structure are made of silicon,
wherein removing the first semiconductor layers in the bottom structure to form the plurality of bottom gaps, and forming the bottom gate in the bottom gaps comprises:
removing the silicon of the bottom structure, and forming the bottom gate in the bottom gaps formed between the plurality of silicon germaniums; and
wherein removing the first semiconductor layers in the top structure to form the plurality of top gaps, and forming the top gate in the top gaps comprises:
removing the silicon germanium of the top structure, and forming the top gate in the top gaps formed between the plurality of silicons.

10. The method according to claim 2, wherein the release protection layer is made of one or more of SiO₂, SiNₓ, HfO₂, AlOₓ, LaOₓ, SiNO, SiCO, SiCNO and SiCN.

11. The method according to claim 2, wherein a thickness of the release protection layer ranges from 0.1 nm to 100 nm.
